(19) United States
(12) Patent Application Publication
(10) Pub. No.: US 2024/0105806 A1
(43) Pub. Date: Mar. 28, 2024

(54) Multi-Gate Devices And Method Of Forming The Same

(71) Applicant: Taiwan Semiconductor Manufacturing Company, Ltd., Hsin-Chu (TW)

(72) Inventors: Che-Lun Chang, Hsinchu (TW); Kuan-Ting Pan, Taipei City (TW); Wei-Yang Lee, Taipei City (TW)

(21) Appl. No.: 18/181,430

(22) Filed: Mar. 9, 2023

Related U.S. Application Data
(60) Provisional application No. 63/410,059, filed on Sep. 26, 2022.

(51) Int. Cl. H01L 29/423; H01L 21/8234; H01L 29/06; H01L 29/66; H01L 29/775; H01L 29/786

(52) U.S. Cl. CPC H01L 29/42392; H01L 21/823412; H01L 21/823418; H01L 21/823481; H01L 29/0673; H01L 29/66439; H01L 29/66545; H01L 29/775; H01L 29/78696

(57) ABSTRACT

Semiconductor structures and methods of forming the same are provided. In an embodiment, an exemplary semiconductor structure includes a vertical stack of channel members disposed over a substrate, a gate structure wrapping around each channel member of the vertical stack of channel members, a source/drain feature coupled to the vertical stack of channel members and adjacent the gate structure; and a dielectric feature disposed between the source/drain feature and the substrate, in a cross-sectional view, the dielectric feature includes a V-shape sidewall surface.

### PRIORITY

This application claims the priority of U.S. Provisional Application Ser. No. 63/410,059, filed Sep. 26, 2022, entitled “Multi-Gate Devices And Method Of Forming The Same,” the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor. While existing GAA transistors may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure, according to one or more aspects of the present disclosure.

FIG. 2 illustrates a fragmentary top view of an exemplary workpiece to undergo various stages of operations in the method of FIG. 1, according to various aspects of the present disclosure.

FIGS. 3, 4, 5, 6, 7, 8, 9, 10, 11, 12, 13, 14, and 15 (FIGS. 3-15) illustrate fragmentary cross-sectional views of the workpiece taken along line A-A′ as shown in FIG. 2 during various fabrication stages in the method of FIG. 1, according to one or more aspects of the present disclosure.

FIG. 16 illustrates a fragmentary cross-sectional view of a first alternative workpiece taken along line A-A′ as shown in FIG. 2, according to one or more aspects of the present disclosure.

FIG. 17 illustrates a fragmentary cross-sectional view of the first alternative workpiece taken along line B-B′ as shown in FIG. 2, according to one or more aspects of the present disclosure.

FIG. 18 illustrates a fragmentary cross-sectional view of a second alternative workpiece taken along line A-A′ as shown in FIG. 2, according to one or more aspects of the present disclosure.

FIG. 19 illustrates a fragmentary cross-sectional view of a third alternative workpiece taken along line A-A′ as shown in FIG. 2, according to one or more aspects of the present disclosure.

FIG. 20 illustrates a fragmentary cross-sectional view of a fourth alternative workpiece taken along line A-A′ as shown in FIG. 2, according to one or more aspects of the present disclosure.

FIG. 21 illustrates a fragmentary cross-sectional view of the fourth alternative workpiece taken along line C-C′ as shown in FIG. 2, according to one or more aspects of the present disclosure.

FIG. 22 illustrates a fragmentary cross-sectional view of the fourth alternative workpiece taken along line B-B′ as shown in FIG. 2, according to one or more aspects of the present disclosure.

FIG. 23 illustrates a fragmentary cross-sectional view of a fifth alternative workpiece taken along line A-A′ as shown in FIG. 2, according to one or more aspects of the present disclosure.

FIG. 24 illustrates a fragmentary cross-sectional view of a sixth alternative workpiece taken along line A-A′ as shown in FIG. 2, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Formation of an MBC transistor includes formation of a stack that includes a number of channel layers interleaved by a number of sacrificial layers over a substrate, where the sacrificial layers may be selectively removed to release the channel layers as channel members by a subsequent etching process. The stack and a top portion of the substrate are patterned to form active regions. The patterned top portion of the substrate may be referred to as a mesa structure. A gate structure that includes a dielectric layer and a conductive layer is then formed to wrap around and over each of the channel members. After the formation of source/drain features, the gate structure and the sacrificial layers may be replaced by a functional gate stack. However, in some instances, MBC transistors may suffer current leakage near the mesa structure. For example, the functional gate stack not only wraps around the channel members disposed over the substrate, but also directly engages the mesa structure under those channel members, leading to strong leakage current flowing into the substrate.

The present disclosure provides a method for semiconductor structures with reduced mesa leakage. In an exemplary method, after forming a fin-shaped active region (including the mesa structure) and forming a dummy gate structure over a channel region of the fin-shaped active region, a first etching process is performed to recess a source/drain region of the fin-shaped active region to form a source/drain opening. After forming inner spacer features, a second etching process (e.g., a wet etching process) is then performed to selectively recess parts of the top portion of the substrate exposed by the source/drain opening to form V-shape grooves. Since sidewalls of the V-shape grooves are not substantially vertical, forming V-shape grooves would facilitate the formation of dielectric features in the V-shape grooves using topology selectivity (TS) technology. After forming the V-shape grooves, dielectric features are selectively formed in the V-shape grooves using topology selectivity (TS) technology. The dielectric features substantially cover sidewall surfaces of the V-shape grooves and thus substantially cover exposed surfaces of the mesa structure. Source/drain features are then formed on the dielectric features. That is, the source/drain features are spaced apart from the substrate by the dielectric features. By forming the dielectric features, leakage current associated with the mesa structure may be advantageously reduced or substantially eliminated. As such, device performance of the semiconductor structure may be improved.

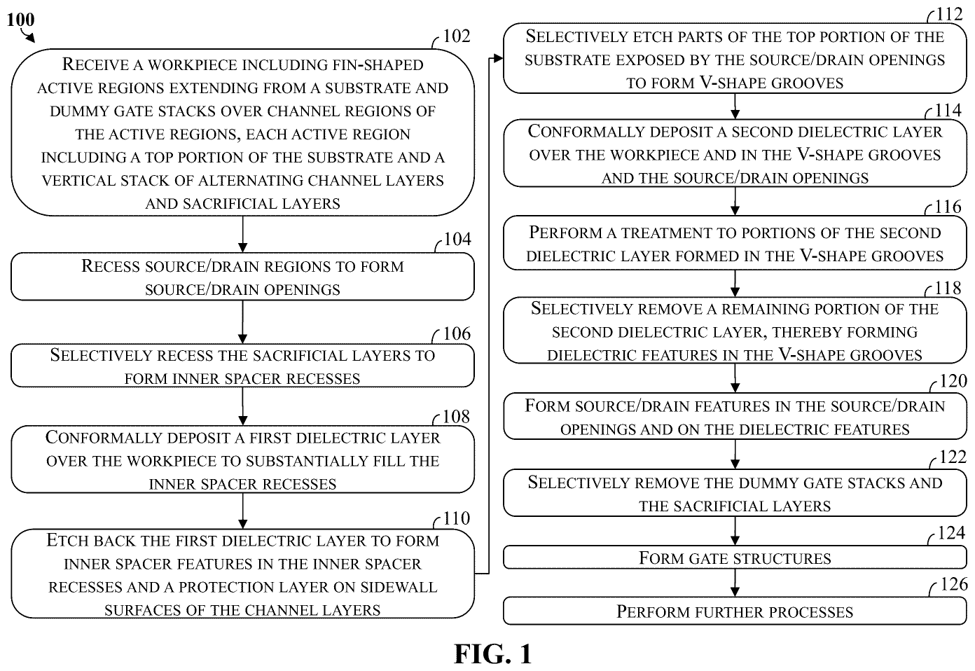

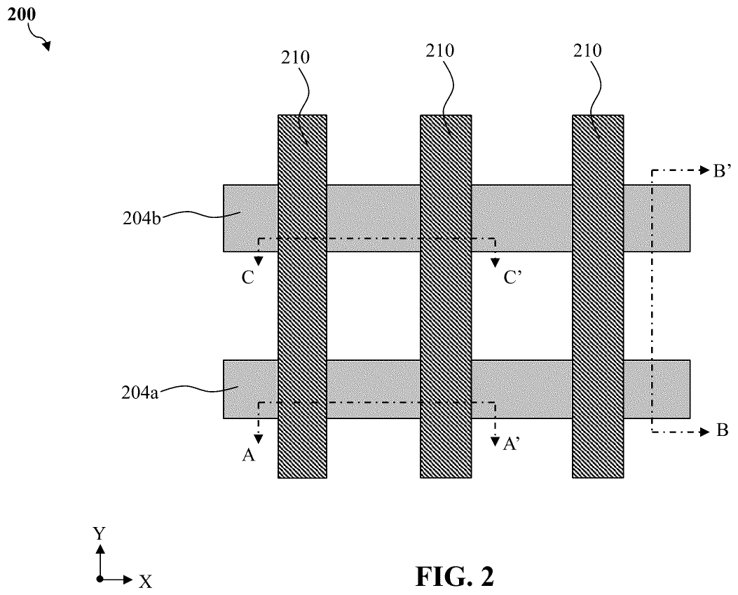

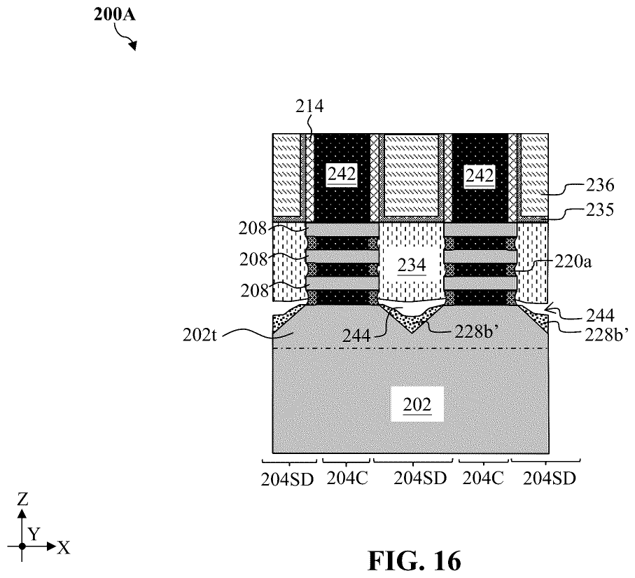

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2 and 3-15, which are fragmentary top/cross-sectional views of a workpiece 200 at different stages of fabrication according to embodiments of method 100. FIGS. 16-24 depict cross-sectional views of workpieces (e.g., workpieces 200A-200F) in alternative embodiments of the present disclosure. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the workpiece 200/200A/200B/200C/200D/200E/200F will be fabricated into a semiconductor structure upon conclusion of the fabrication processes, the workpiece 200/200A/200B/200C/200D/200E/200F may be referred to as the semiconductor structure 200/200A/200B/200C/200D/200E/200F as the context requires. For avoidance of doubts, the X, Y and Z directions in FIGS. 2 and 3-24 are perpendicular to one another and are used consistently throughout the present disclosure. Throughout the present disclosure, like reference numerals denote like features unless otherwise excepted.

Referring to FIGS. 1, 2, and 3, method 100 includes a block 102 where a workpiece 200 is received. The workpiece 200 includes a substrate 202. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GalnAs, GaInP, GaInAsP, or combinations thereof. In some alternative embodiments, the substrate 202 may be a semiconductor-on-insulator substrate, such as a silicon-on-insulator substrate, a silicon germanium-on-insulator substrate, or a germanium-on-insulator substrate. The substrate 202 may include n-type doped region(s) and p-type doped region(s).

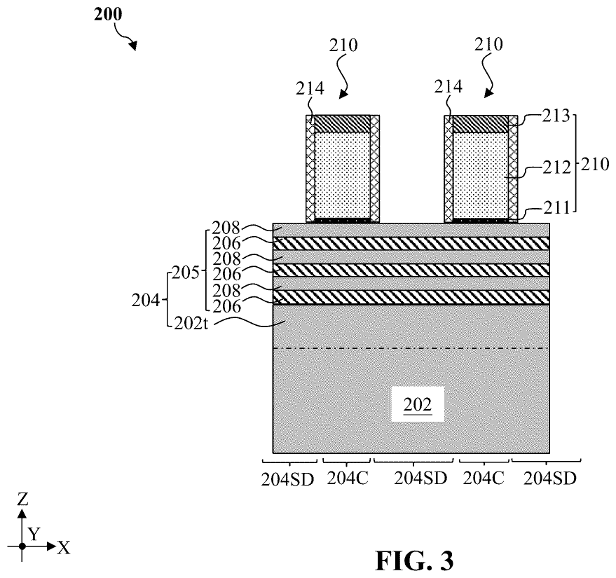

The workpiece 200 includes a number of fin-shaped active regions such as 204a and 204b disposed over the substrate 202. In the present embodiments, the fin-shaped active region 204a would be used to facilitate the formation of N-type transistors, and the fin-shaped active region 204b would be used to facilitate the formation of P-type transistors. The fin-shaped active regions 204a and/or 204b may be individually or collectively referred to as fin-shaped active region(s) 204. The fin-shaped active region 204 extends lengthwise along the X direction and is divided into channel regions 204C overlapped by dummy gate stacks 210 (to be described below) and source/drain regions 204SD not overlapped by the dummy gate stacks 210. Source/drain region(s) may refer to a source region or a drain region, individually or collectively dependent upon the context. The numbers of fin-shaped active regions 204, channel regions 204C, and source/drain regions 204SD shown in FIGS. 2 and 3 are for illustration purpose only and should not be construed as limiting the scope of the present disclosure. The fin-shaped active region 204 is formed from a top portion 202t of the substrate 202 and a vertical stack 205 of alternating semiconductor layers 206 and 208 using a combination of lithography and etch steps. That is, the fin-shaped active region 204 includes a patterned vertical stack 205 and a patterned top portion 202t of the substrate 202 thereunder. The patterned top portion 202t of the substrate 202 that is formed directly under the patterned vertical stack 205 may be referred to as a mesa structure 202t. An exemplary lithography process includes spin-on coating a photoresist layer, soft baking of the photoresist layer, mask aligning, exposing, post-exposure baking, developing the photoresist layer, rinsing, and drying (e.g., hard baking). In some instances, the patterning of the fin-shaped active region 204 may be performed using double-patterning or multi-patterning processes to create patterns having pitches smaller than what is otherwise obtainable using a single, direct photolithography process. The etching process can include dry etching, wet etching, and/or other suitable processes. In the depicted embodiment, the vertical stack 205 of alternating semiconductor layers 206 and 208 may include a number of channel layers 208 interleaved by a number of sacrificial layers 206. Each of the channel layers 208 may be formed of silicon (Si) and each of the sacrificial layers 206 may be formed of silicon germanium (SiGe). The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes.

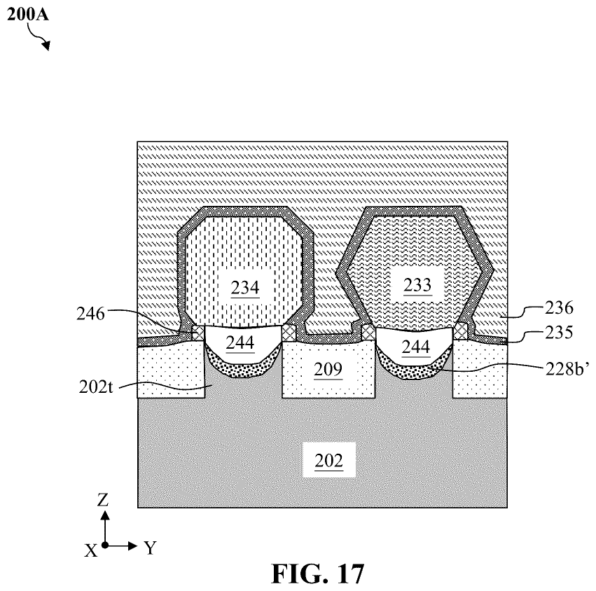

While not explicitly shown in FIGS. 2 and 3, the workpiece 200 also includes an isolation feature 209 (shown in FIG. 17) formed around each fin-shaped active region 204 to isolate the fin-shaped active region 204 from an adjacent fin-shaped active region. The isolation feature 209 may also be referred to as a shallow trench isolation (STI) feature and may include silicon oxide, silicon oxynitride, fluorine-doped silicate glass (FSG), a low-k dielectric, combinations thereof, and/or other suitable materials.

Still referring to FIGS. 2 and 3, the workpiece 200 also includes dummy gate stacks 210 disposed over channel regions 204C of the fin-shaped active region 204. The channel regions 204C and the dummy gate stacks 210 also define source/drain regions 204SD that are not vertically overlapped by the dummy gate stacks 210. Each of the channel regions 204C is disposed between two source/drain regions 204SD along the X direction.

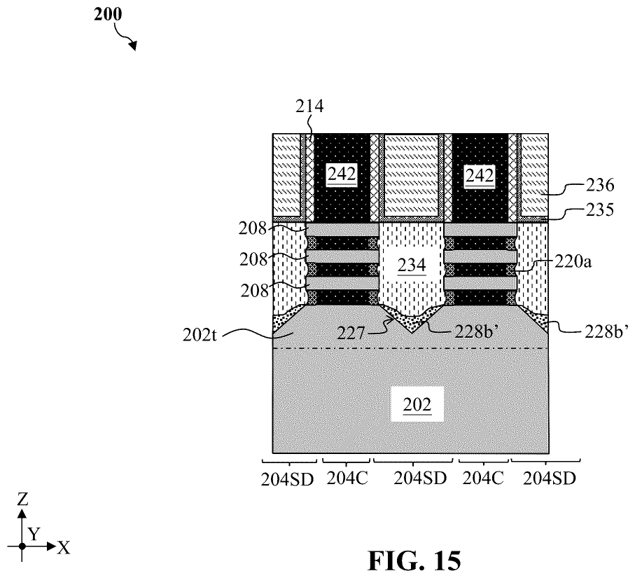

Three dummy gate stacks 210 are shown in FIG. 2 but the workpiece 200 may include any suitable number of dummy gate stacks 210. In this embodiment, a gate replacement process (or gate-last process) is adopted where the dummy gate stacks 210 serve as placeholders for functional gate structures (e.g., gate structures 242 shown in FIG. 15). Other processes and configurations are possible. The dummy gate stack 210 includes a dummy dielectric layer 211, a dummy gate electrode layer 212 over the dummy dielectric layer 211, and a gate-top hard mask layer 213 over the dummy gate electrode layer 212. The dummy dielectric layer 211 may include silicon oxide. The dummy gate electrode layer 212 may include polysilicon. The gate-top hard mask layer 213 may include silicon oxide layer, silicon nitride, and/or other suitable materials. Suitable deposition process, photolithography and etching process may be employed to form the dummy gate stack 210. As shown in FIG. 3, the workpiece 200 also includes gate spacers 214 disposed along sidewalls of the dummy gate stack 210. In some embodiments, the gate spacer 214 may include silicon oxide, silicon oxycarbide, silicon carbonitride, silicon nitride, zirconium oxide, aluminum oxide, or a suitable dielectric material.

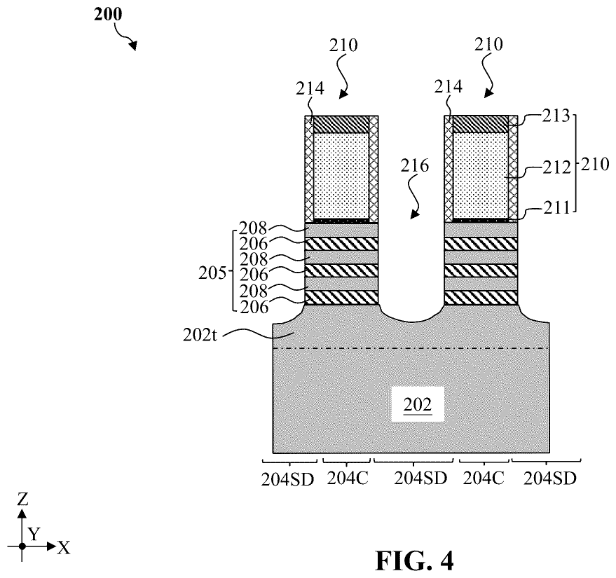

Referring to FIGS. 1 and 4, method 100 includes a block 104 where source/drain regions 204SD of the fin-shaped active regions 204 are recessed to form source/drain openings 216. In some embodiments, the source/drain regions 204SD are anisotropically etched by a plasma etch with a suitable etchant, such as fluorine-containing etchant, oxygen-containing etchant, hydrogen-containing etchant, a fluorine-containing etchant (e.g., CF₄, SF₆, CH₂F₂, CHF₃, and/or C₂F₆), a chlorine-containing etchant (e.g., Cl₂, CHCl₃, CCl₄, and/or BCl₃), a bromine-containing etchant (e.g., HBr and/or CHBr₃), an iodine-containing etchant, other suitable etchants, and/or combinations thereof. In embodiments represented in FIG. 4, the source/drain openings 216 extend through the vertical stack 205 and slightly extend into the top portion 202t of the substrate 202. As illustrated in FIG. 4, sidewalls of the channel layers 208 and the sacrificial layers 206 and top surfaces of parts of the top portion 202t are exposed in the source/drain openings 216.

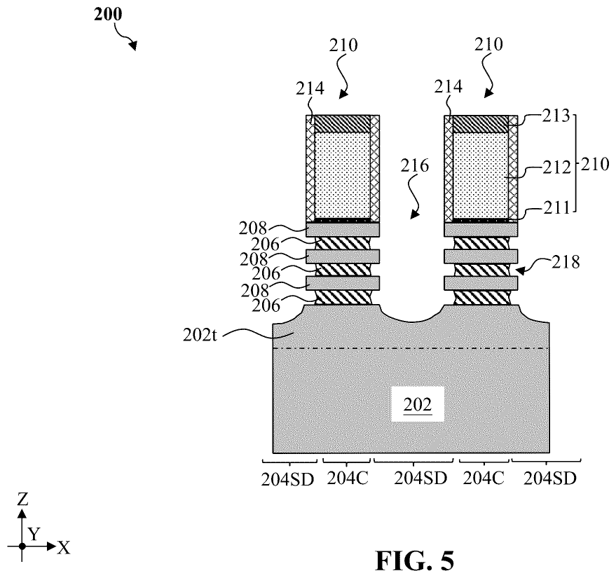

Referring to FIGS. 1 and 5, method 100 includes a block 106 where the sacrificial layers 206 are selectively recessed to form inner spacer recesses 218. After the formation of the source/drain openings 216, the sacrificial layers 206 are exposed in the source/drain openings 216. As shown in FIG. 5, the sacrificial layers 206 are selectively and partially recessed to form inner spacer recesses 218, while the exposed channel layers 208 are substantially unetched. In embodiments where the channel layers 208 consist essentially of silicon (Si) and sacrificial layers 206 consist essentially of silicon germanium (SiGe), the selective and partial recess of the sacrificial layers 206 may include use of a selective isotropic etching process (e.g., a selective dry etching process or a selective wet etching process), and the extent at which the sacrificial layers 206 are recessed is controlled by duration of the etching process.

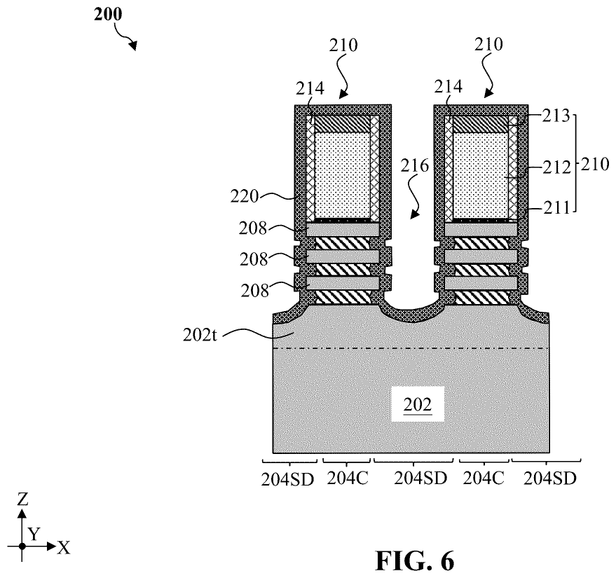

Referring to FIGS. 1 and 6, method 100 includes a block 108 where a first dielectric layer 220 is conformally deposited over the workpiece 200, including in the inner spacer recesses 218, by ALD, CVD, or any other suitable deposition process. The term “conformally” may be used herein for ease of description of a layer having substantially uniform thickness over various regions of the workpiece 200. In the present embodiments, the thickness of the first dielectric layer 220 is selected such that the first dielectric layer 220 substantially fills the inner spacer recesses 218. It is noted that, due to the conformal deposition of the first dielectric layer 220, a shape of the first dielectric layer 220 tracks the shape of the workpiece 200. The first dielectric layer 220 may include silicon oxide, silicon nitride, silicon oxycarbide, silicon oxycarbonitride, silicon carbonitride, metal nitride, or other suitable dielectric materials.

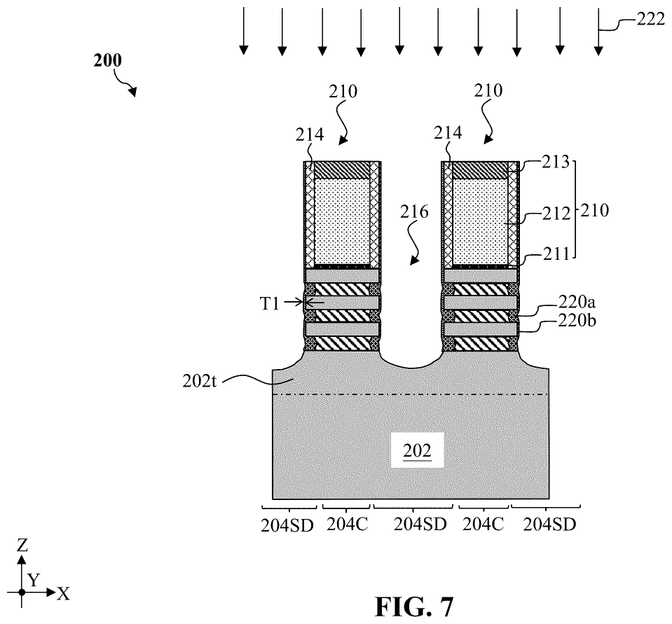

Referring to FIGS. 1 and 7, method 100 includes a block 110 where the first dielectric layer 220 is etched back to form inner spacer features 220a in the inner spacer recesses 218. An etching process 222 may be performed to etch back the first dielectric layer 220, thereby forming the inner spacer features 220a as shown in FIG. 7. In some embodiments, the etching process 222 may be a dry etching process and in a way similar to the dry etching process used in the formation of the source/drain openings 216. In the present embodiments, duration of the etching process 222 is controlled such that a portion 220b of the first dielectric layer 220 remains on the sidewall surfaces of the channel layers 208 and sidewall surfaces of the gate spacers 214. The portion 220b of the first dielectric layer 220 may be used to protect the channel layers 208 in a subsequent etching process 224 and may be referred to as a protection layer 220b. In some embodiments, a thickness T1 of the protection layer 220b is between 1 nm and about 3 nm.

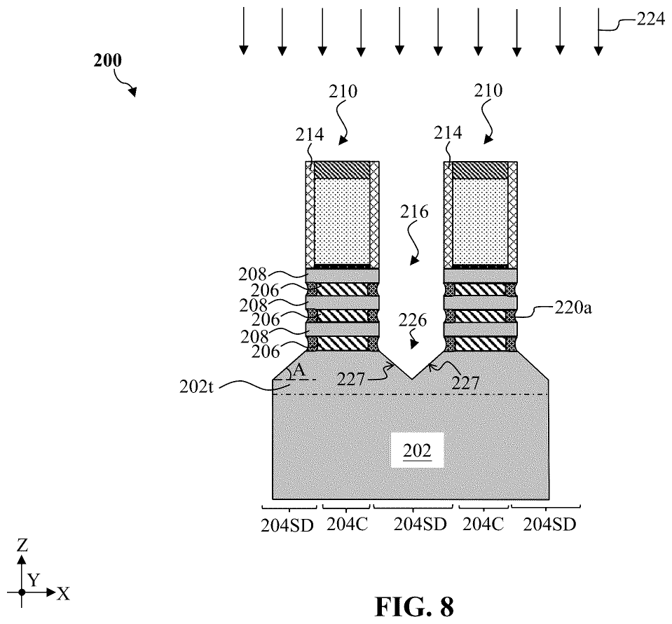

Referring to FIGS. 1 and 8, method 100 includes a block 112 where an etching process 224 is performed to selectively etch parts of the top portion 202t of the substrate 202 exposed by the source/drain openings 216 to form V-shape grooves 226. In the illustrated embodiment, two sidewalls 227 of the V-shape groove 226 intersect with each other at a vertex, defining a V-shape in a cross-sectional view of the V-shape groove 226. The V-shape groove 226 is formed by recessing parts of the top portion 202t of the substrate 202 exposed by the source/drain openings 216. In the present embodiments, the semiconductor substrate 202 includes a (100) silicon, and the etching process 224 includes a wet etching process 224. The wet etching process 224 is selective to (111) crystallographic planes of silicon. That is, the etchant of the wet etching process 224 etches silicon at a much slower rate along the (111) crystallographic planes of silicon. In other words, the sidewalls 227 of the V-shape groove 226 are (111) crystallographic planes of the (100) silicon substrate. In the present embodiments, the sidewall 227 of the V-shape groove 226 and the X-axis forms an angle A, the angle A is about 55°, such as from about 50° to about 60°, due to process variations during the etching. The wet etching process 224 may implement ammonia (NH 3) as an etchant. The etching process 224 further removes the protection layer 220b.

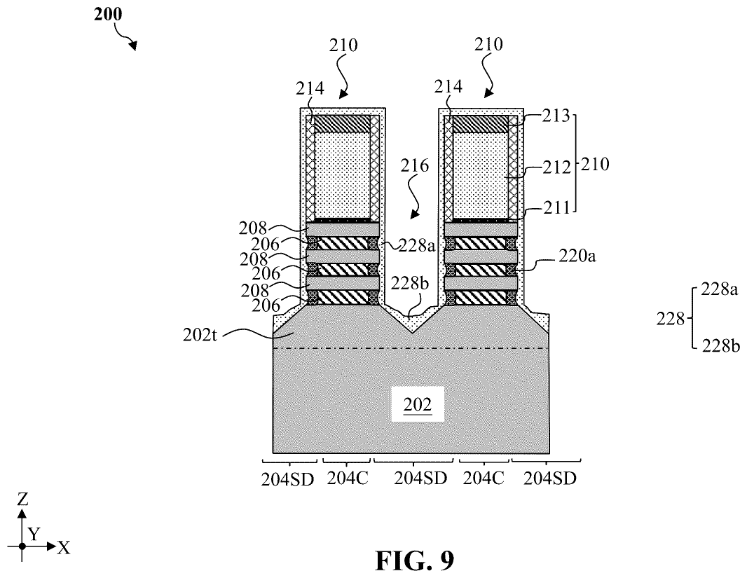

Referring to FIGS. 1 and 9, method 100 includes a block 114 where a second dielectric layer 228 is conformally deposited over the workpiece 200 and in the V-shaped grooves 226 and the source/drain openings 216. The second dielectric layer 228 may be deposited by ALD, CVD, or any other suitable deposition process. It is noted that, due to the conformal deposition of the second dielectric layer 228, a shape of the second dielectric layer 228 generally tracks the shape of the workpiece 200. For example, a portion 228a of the second dielectric layer 228 that extends along sidewall surfaces of the channel layers 208 and the inner spacer features 220a has a uniform thickness. However, due to the V-shape groove 226, a portion 228b of the second dielectric layer 228 formed in the V-shape groove 226 and/or at the bottom portion of the V-shape groove 226 may merge during the deposition process. As such, the portion 228b of the second dielectric layer 228 formed in the V-shape groove 226 has a non-uniform thickness. The portion 228b of the second dielectric layer 228 substantially covers exposed top surfaces of the mesa structure 202t adjacent the channel region 204C. In the present embodiments, the composition of the second dielectric layer 228 is selected such that, after a subsequent treatment, there is an etch selectivity between the portion 228b formed in the V-shape groove 226 and a remaining portion 228a of the second dielectric layer 228. In an embodiment, the second dielectric layer 228 includes a nitride-based material, such as silicon nitride.

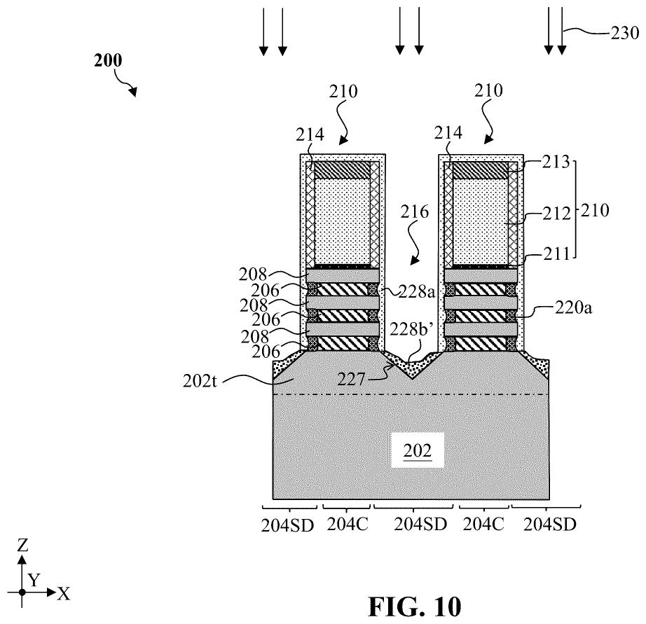

Referring to FIGS. 1 and 10, method 100 includes a block 116 where a treatment 230 is performed to the portion 228b of the second dielectric layer 228 formed in the V-shaped grooves 226. In an embodiment, the treatment 230 includes a plasma treatment. In the present embodiments, the treatment 230 is only applied to the portion 228b formed in the V-shaped grooves 226 to harden the portion 228b of the second dielectric layer 228 so as to increase its structural stability. The hardened portion 228b of the second dielectric layer 228 may be referred to as a dielectric feature 228b′. Chemical characteristics of the dielectric feature 228b′ are thus different from the untreated portion 228a of the second dielectric layer 228. For example, there is an etch selectivity between the dielectric feature 228b′ and the untreated portion 228a of the second dielectric layer 228.

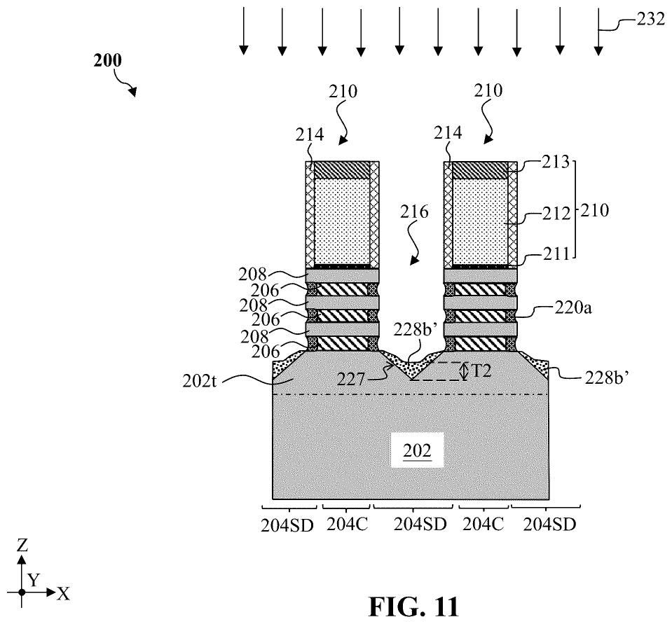

Referring to FIGS. 1 and 11, method 100 includes a block 118 where an etching process 232 is performed to selectively remove the untreated portion 228a of the second dielectric layer 228. The etching process 232 selectively removes the untreated portion 228a of the second dielectric layer 228 without substantially etching the dielectric feature 228b′, the channel layers 208, the inner spacer features 220a, and the gate spacers 214. In an embodiment, the etching process 232 includes implementing dilute hydrofluoric acid (DHF). A thickness T2 of the dielectric feature 228b′ may be between about 1 nm and about 20 nm. The thickness T2 may be a distance between a bottommost point of a top surface of the dielectric feature 228b′ and the vertex of the V-shape groove 226. The top surface of the dielectric feature 228b′ may be coplanar with or below a bottom surface of a bottommost channel layer 208 of the channel layers 208.

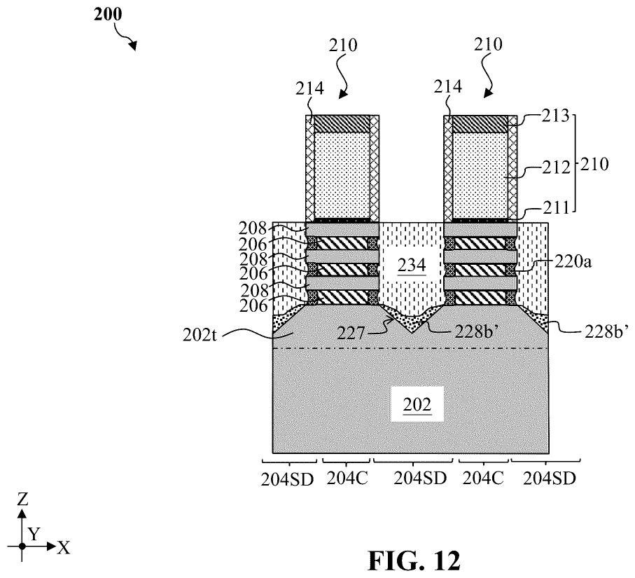

Referring to FIGS. 1 and 12, method 100 includes a block 120 where source/drain features are formed in the source/drain openings 216 and on the dielectric features 228b′. Source/drain feature(s) may refer to a source feature or a drain feature, individually or collectively dependent upon the context. Depending on the conductivity type of the to-be-formed transistor, the source/drain features may be n-type source/drain features or p-type source/drain features. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In this illustrated example in FIG. 12, which is a fragmentary cross-sectional view taken along line A-A′ of the fin-shaped active region 204a, the source/drain features 234 are N-type source/drain features. The source/drain feature 234 is spaced apart from the substrate 202 by the dielectric feature 228b′. Due to the formation of the dielectric feature 228b′, the source/drain feature 234 may be free of an undoped semiconductor layer. Thus, after the sacrificial layers 206 are selectively removed and metal gate structures are formed to wrap around and over the channel layers 208, no planar transistors would be formed near the mesa structure 202t. Therefore, leakage current generated due to poor gate control of the planar transistors may be substantially eliminated. Although not separately labeled, the source/drain features 234 may include a second doped epitaxial semiconductor layer embedded in a first doped epitaxial semiconductor layer. Both the first doped epitaxial semiconductor layer and the second doped epitaxial semiconductor layer are exposed from a top surface of the source/drain feature 234. A concentration of dopants in the second doped epitaxial semiconductor layer is greater than a concentration of dopants in the first doped epitaxial semiconductor layer.

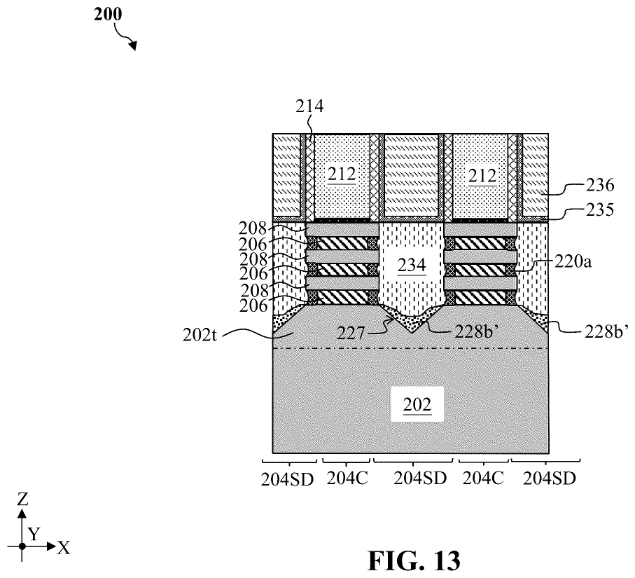

Referring to FIGS. 1 and 13-14, method 100 includes a block 122 where the dummy gate stacks 210 and the sacrificial layers 206 are selectively removed in a sequential order. In an embodiment represented in FIG. 13, a contact etch stop layer (CESL) 235 and an interlayer dielectric (ILD) layer 236 are deposited over the workpiece 200. The CESL 235 may include silicon nitride, silicon oxynitride, and/or other suitable materials and may be formed by ALD, plasma-enhanced chemical vapor deposition (PECVD) process and/or other suitable deposition or oxidation processes. The ILD layer 236 is deposited by a PECVD process or other suitable deposition technique over the workpiece 200 after the deposition of the CESL 235. The ILD layer 236 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process, such a chemical mechanical polishing (CMP) process may be performed to the workpiece 200 to remove excess materials and expose top surfaces of the dummy gate electrode layers 212 in the dummy gate stacks 210.

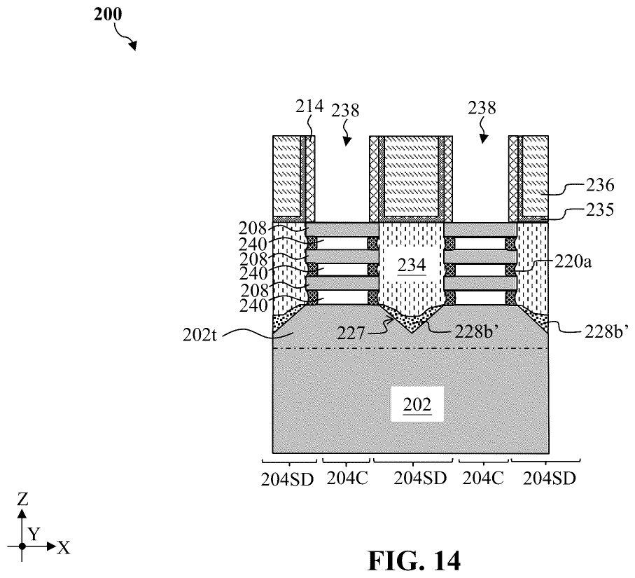

With the exposure of the dummy gate electrode layers 212, block 122 proceeds to removal of the dummy gate stacks 210. The removal of the dummy gate stacks 210 may include one or more etching process selective to the materials in the dummy gate stacks 210 and form gate trenches 238. For example, the removal of the dummy gate stacks 210 may be performed using a selective wet etch, a selective dry etch, or a combination thereof. In embodiments represented in FIG. 14, after the removal of the dummy gate stacks 210, the sacrificial layers 206 are selectively removed to release the channel layers 208 as channel members 208 in the channel regions 204C. The removal of the sacrificial layers 206 forms gate openings 240. The selective removal of the sacrificial layers 206 may be implemented by a selective dry etch, a selective wet etch, or other selective etching process. In some embodiments, the selective wet etching includes an APM etch (e.g., ammonia hydroxide-hydrogen peroxide-water mixture).

Referring to FIGS. 1 and 15, method 100 includes a block 122 where gate structures 242 are formed in the gate trenches 238 and gate openings 240. The gate structures 242 are deposited to wrap over the channel members 208. Although not separately labeled, each of the gate structures 242 may include a gate dielectric layer and a gate electrode layer over the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material.

The gate electrode layer is then deposited over the gate dielectric layer using atomic layer deposition (ALD), physical vapor deposition (PVD), chemical vapor deposition (CVD), e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the semiconductor structure 200 includes n-type transistors and p-type transistors, different gate electrode layers may be formed separately for n-type transistors and p-type transistors, which may include different work function metal layers (e.g., for providing different n-type and p-type work function metal layers).

Referring to FIG. 1, method 100 includes a block 126 where further processes are performed to finish the fabrication of the workpiece 200. Such further processes may include forming source/drain contacts electrically coupled to source/drain features. Such further processes may also include forming a multi-layer interconnect (MLI) structure (not depicted) over the workpiece 200. In some embodiments, the MLI structure may include multiple intermetal dielectric (IMD) layers and multiple metal lines or contact vias in each of the IMD layers. In some instances, the IMD layers and the ILD layer 236 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers.

In methods and structures depicted above, the source/drain feature 234 is in direct contact with the dielectric feature 228b′. In some other implementations, the epitaxial growth recipe for forming the source/drain features may be adjusted to provide other configurations. For example, in embodiments represented in FIG. 16, a fragmentary cross-sectional view of a workpiece 200A is illustrated. The workpiece 200A is similar to the workpiece 200 represented in FIG. 15, except that the workpiece 200A further includes air gaps 244 disposed between the source/drain features 234/233 (shown in FIG. 17) and the corresponding dielectric features 228b′. The epitaxial growth recipe for forming the source/drain feature 234/233 may be adjusted such that portions of the epitaxial layers formed on the sidewall surfaces of channel members 208 may merge earlier, thereby forming the air gaps 244. Forming the air gaps 244 may advantageously reduce a parasitic capacitance of a final structure of the semiconductor device. Thus, high speed performance of the semiconductor device may be improved. A bottom surface of the source/drain feature 234/233 is below or coplanar with a bottom surface of a bottommost channel member 208 of the channel members. In an embodiments, the air gap 244 partially exposes a sidewall surface of a bottommost inner spacer features 220a of the inner spacer features 220a. FIG. 17 depicts a cross-sectional view of the workpiece 200A taken along line B-B′ as shown in FIG. 2. The workpiece 200A includes a p-type source/drain feature 233 adjacent the n-type source/drain feature 234. The workpiece 200A also includes fin sidewall spacers 246 formed on the STI features 209 and under the source/drain features 233/234. The fin sidewall spacers 246 may be formed along with the gate spacers 214, and a composition and a thickness of the fin sidewall spacers 246 may be same as those of the gate spacers 214.

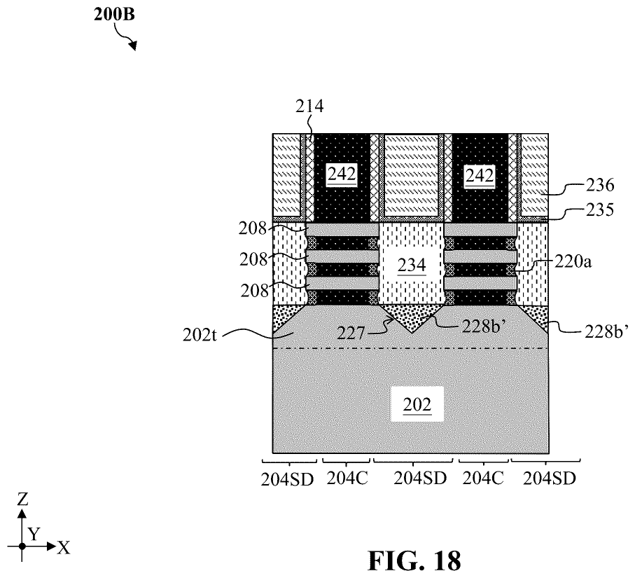

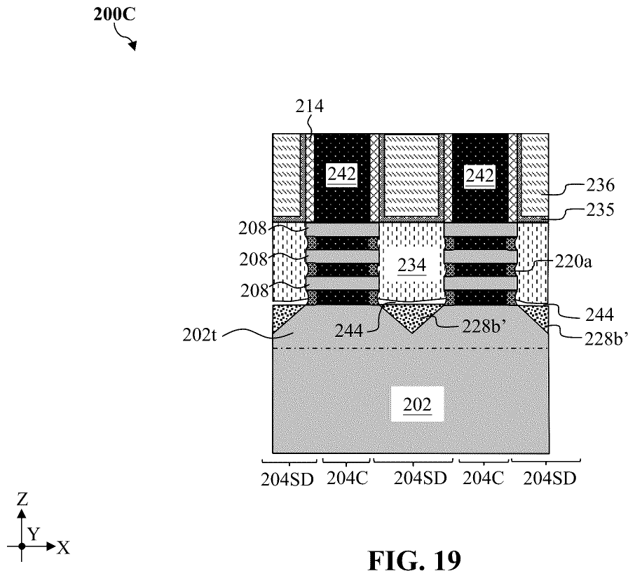

In some other implementations, the deposition thickness of the second dielectric layer 228 for forming the dielectric feature 228b′ may be adjusted to provide other configurations. For example, in embodiments represented in FIG. 18, a fragmentary cross-sectional view of a workpiece 200B is illustrated. The workpiece 200B is similar to the workpiece 200 represented in FIG. 15, except that the profile of the dielectric feature 228b′ in the workpiece 200B is different than that in the workpiece 200. More specifically, during the formation of the second dielectric layer 228 (shown in FIG. 9), a deposition thickness of the second dielectric layer 228 may be increased such that the merged portion of the second dielectric layer 228 may substantially fill the V-shape groove 226. Thus, after performing the operations in blocks 116-118 of method 100 described with reference to FIG. 1, the dielectric feature 228b′ in workpiece 200B may have a substantially planar top surface. In the present embodiments, a shape of a cross-sectional view of the dielectric feature 228b′ in workpiece 200B includes a triangle shape. Further, the epitaxial growth recipe for forming the source/drain features in workpiece 200B may be adjusted. For example, in embodiments represented in FIG. 19, by adjusting the epitaxial growth recipe for forming the source/drain features in workpiece 200B, a workpiece 200C that includes air gaps 244 are formed, and the source/drain feature 234 is spaced apart from the dielectric feature 228b′ by the air gap 244.

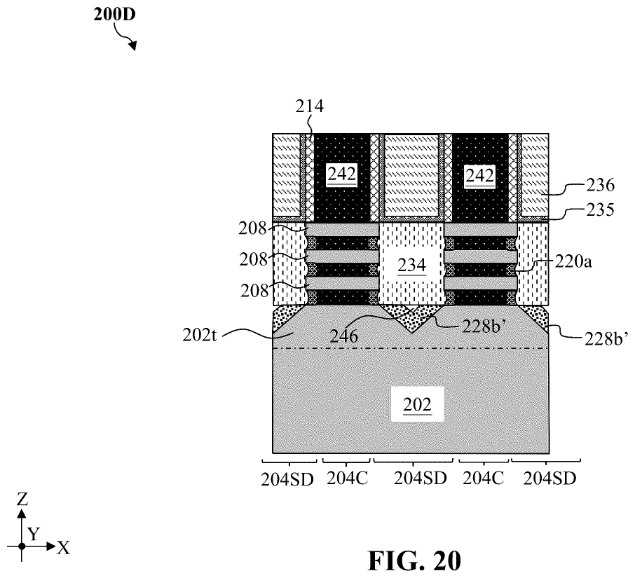

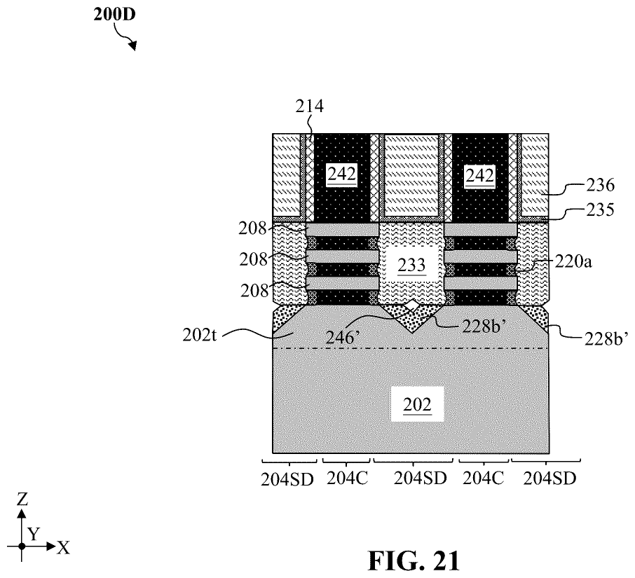

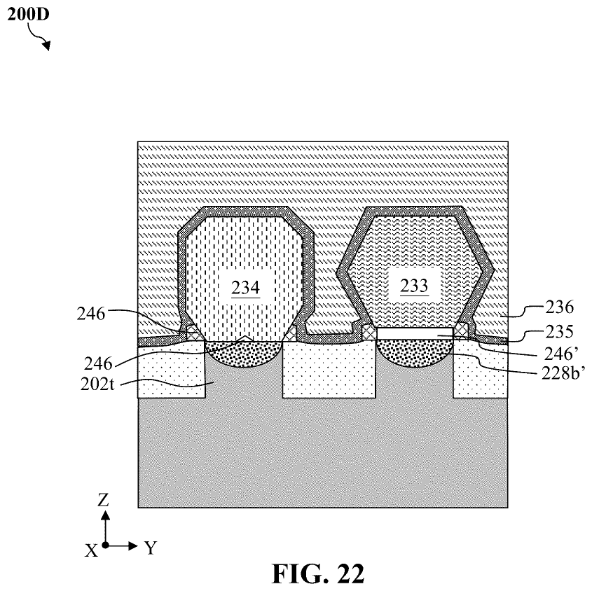

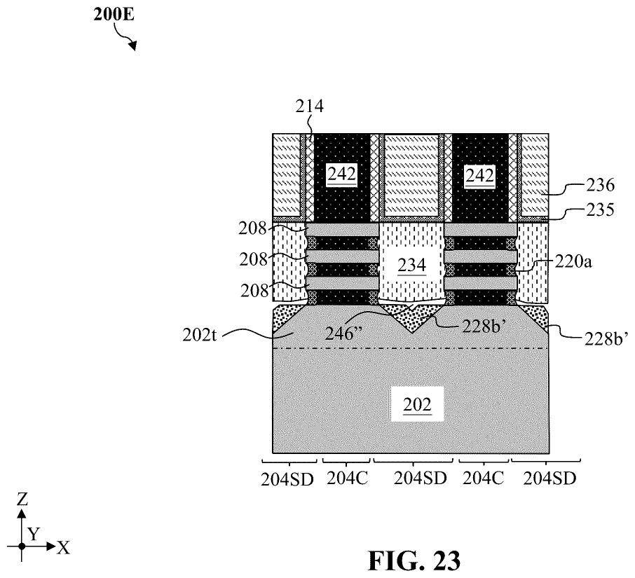

In some other implementations, the deposition thickness of the second dielectric layer 228 for forming the dielectric feature 228b′ may be ranged between the deposition thickness of the dielectric layer 228 associated with the workpiece 200 and the deposition thickness of the dielectric layer 228 associated with the workpiece 200B. For example, in embodiments represented in FIG. 20, a profile of the dielectric feature 228b′ in workpiece 200D is different than that in the workpiece 200 and that in the workpiece 200B. A volume of the dielectric feature 228b′ in workpiece 200D is greater than that in the workpiece 200 and is less than that in the workpiece 200B. After forming the n-type source/drain feature 234, an air gap 246 is formed. The air gap 246 is enclosed by the dielectric feature 228b′ and the source/drain feature 234. FIG. 21 depicts a fragmentary cross-sectional view of the workpiece 200D taken along line C-C′ as shown in FIG. 2. FIG. 22 depicts a fragmentary cross-sectional view of the workpiece 200D taken along line B-B′ as shown in FIG. 2. The workpiece 200D includes the p-type source/drain feature 233 and an air gap 246′ disposed between the p-type source/drain feature 233 and the dielectric feature 228b′. In an embodiment, the p-type source/drain feature 233 includes SiGe, and the n-type source/drain feature 234 includes Si. Since SiGe grows faster in a lateral direction than Si, portions of epaxial layers formed on sidewalls of channel members 208 of a p-type GAA device may merge earlier than those of an n-type GAA device, leading to a larger air gap 246′. That is, under same fabrication processes, a volume of the air gap 246′ formed in a p-type GAA device (e.g., workpiece 200D shown in FIG. 21) is greater than a volume of the air gap 246 formed in an n-type GAA device (e.g., workpiece 200D shown in FIG. 20). Although not described in detail, this relationship also applies to the airgaps in p-type GAA device and n-type devices in the workpieces 200A and 200C as well. As described above, the epitaxial growth recipe for forming the p-type source/drain feature 233/n-type source/drain feature 234 may be further adjusted. FIG. 23 depicts a fragmentary cross-sectional view of a workpiece 200E taken along line A-A′ as shown in FIG. 2. The workpiece 200E is similar to the workpiece 200D represented in FIG. 20, except that a volume of the air gap 246″ is greater than the volume of the air gap 246. The epitaxial growth recipe for forming the p-type source/drain feature 233 may be also adjusted to provide a larger air gap for the p-type GAA device represented in FIG. 21.

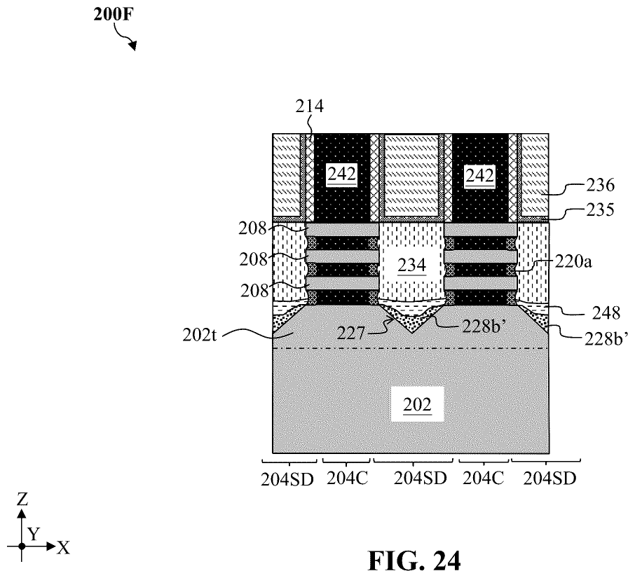

In some other implementations, instead of forming air gaps, another dielectric layer may be formed on the dielectric feature 228b′ to reduce the parasitic capacitance while providing a better control on the performance of the workpiece. Reference now made to FIG. 24, where a fragmentary cross-sectional view of a workpiece 200F is shown. The workpiece 200F is similar to the workpiece 200 or 200A, expect that the workpiece 200F includes a dielectric layer 248. In an embodiment, after the formation of the dielectric feature 228b′, a dielectric layer 248 may be formed on the dielectric feature 228b′. The dielectric layer 248 may include a low-k material. In some embodiments, the dielectric layer 248 may include SiCN, SiOCN, SiOC, or SiON. The source/drain feature (e.g., the source/drain feature 234) may be spaced apart from the dielectric feature 228b′ by the dielectric layer 248. A top surface of the dielectric layer 248 may be coplanar with or below a bottom surface of a bottommost channel member 208 of the channel members 208.

Although not intended to be limiting, one or more embodiments of the present disclosure provide many benefits to a semiconductor structure and the formation thereof. The present disclosure provides V-shape dielectric features configured to cover mesa structures so as to reduce or substantially eliminate leakage current near mesa structure of multi-gate devices (e.g., such as a GAA transistors) to thus improve the performance of the semiconductor structure. The V-shape dielectric feature is disposed between a source/drain feature and a substrate. The source/drain feature may do not include an undoped epitaxial layer. In some embodiments, air gaps may be formed between the dielectric features and source/drain features to further reduce a parasitic capacitance of the semiconductor structure.

The present disclosure provides for many different embodiments. Semiconductor structures and methods of fabrication thereof are disclosed herein. In one exemplary aspect, the present disclosure is directed to a method. The method includes receiving a workpiece comprising a channel region extending from a substrate and comprising a plurality of channel layers interleaved by a plurality of sacrificial layers, a source/drain region adjacent the channel region, and a dummy gate structure over the channel region. The method also includes performing a first etching process to recess the source/drain region to form a source/drain opening, the source/drain opening exposing the substrate, performing a second etching process to the substrate, resulting in a V-shape groove in the substrate, forming a dielectric feature in the V-shape groove, after the forming of the dielectric feature, forming a source/drain feature on the dielectric feature to fill the source/drain opening, selectively removing the dummy gate structure, selectively removing the plurality of sacrificial layers, and forming a metal gate stack to wrap around each channel layer of the plurality of channel layers.

In some embodiments, the forming of the dielectric feature in the V-shape groove may include conformally depositing a dielectric layer over the workpiece, the dielectric layer comprising a first portion extending along sidewalls of the source/drain opening and a second portion in the V-shape groove, performing a plasma treatment to the second portion of the dielectric layer, and performing a third etching process to selectively remove the first portion of the dielectric layer, leaving the treated second portion of the dielectric layer in the V-shape groove. In some embodiments, the dielectric layer may include silicon nitride, and the third etching process may include implementing dilute hydrofluoric acid (DHF). In some embodiments, an angle between a sidewall of the V-shape groove and a bottom surface of the substrate may be between about 50 o and about 60 o. In some embodiments, the second etching process may include a wet etching process. In some embodiments, the method may also include selectively etching the sacrificial layers to form inner spacer recesses, conformally depositing a dielectric layer over the workpiece to fill the inner spacer recesses, etching back the dielectric layer to form inner spacer features in the inner spacer recesses and a protection layer extending along sidewall surfaces of the channel layers. In some embodiments, the performing of the second etching process may also remove the protection layer. In some embodiments, the method may also include, after the forming of the dielectric feature, forming a low-k dielectric layer on the dielectric feature, the source/drain feature may be spaced apart from the low-k dielectric layer by the dielectric feature.

In another exemplary aspect, the present disclosure is directed to a method. The method includes forming a dummy gate structure engaging a semiconductor fin, the semiconductor fin comprising a top portion of a substrate and a vertical stack of alternating channel layers and sacrificial layers thereon, recessing a portion of the semiconductor fin not covered by the dummy gate structure to form a source/drain opening, selectively recessing the sacrificial layers to form inner spacer recesses, forming inner spacer features in the inner spacer recesses, performing a wet etching process to selectively etch the top portion of the substrate exposed by the source/drain opening, thereby forming an extended source/drain opening, forming an isolation structure in the extended source/drain opening, forming a source/drain feature on the isolation structure and in the extended source/drain opening, and replacing the sacrificial layers and the dummy gate structure with a metal gate stack.

In some embodiments, the performing of the wet etching process may include implementing ammonia. In some embodiments, in a cross-sectional view, the extended source/drain opening may include a V-shape lower portion. In some embodiments, the forming of the source/drain feature may include forming a doped epitaxial layer in the extended source/drain opening, where the doped epitaxial layer may be spaced apart form the substrate by the isolation structure. In some embodiments, the isolation structure may include a dielectric layer on the substrate and an air gap between the dielectric layer and the source/drain feature. In some embodiments, the forming of the isolation structure may include conformally depositing a dielectric layer in the extended source/drain opening, performing a treatment to a portion of the dielectric layer in direct contact with the substrate without treating a remaining portion of the dielectric layer, selectively removing the remaining portion of the dielectric layer without removing the treated portion of the dielectric layer, thereby forming the isolation structure. In some embodiments, the substrate may include (100) silicon, and the extended source/drain opening may expose (111) crystallographic planes of the substrate.

In yet another exemplary aspect, the present disclosure is directed to a semiconductor structure. The semiconductor structure includes a vertical stack of channel members disposed over a substrate, a gate structure wrapping around each channel member of the vertical stack of channel members, a source/drain feature coupled to the vertical stack of channel members and adjacent the gate structure, and a dielectric feature disposed between the source/drain feature and the substrate, wherein, in a cross-sectional view, the dielectric feature comprises a V-shape sidewall surface.

In some embodiments, an entirety of a bottom surface of the source/drain feature may be in direct contact with the dielectric feature. In some embodiments, the semiconductor structure may also include an air gap disposed between the source/drain feature and the dielectric feature. In some embodiments, the dielectric feature may include silicon nitride. In some embodiments, the V-shape sidewall surface may include a first sidewall intersecting a second sidewall at a vertex, and the first sidewall may include a (111) crystallographic plane.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising:
a channel region extending from a substrate and comprising a plurality of channel layers interleaved by a plurality of sacrificial layers,
a source/drain region adjacent the channel region, and
a dummy gate structure over the channel region;
performing a first etching process to recess the source/drain region to form a source/drain opening, the source/drain opening exposing the substrate;
performing a second etching process to the substrate, resulting in a V-shape groove in the substrate;
forming a dielectric feature in the V-shape groove;
after the forming of the dielectric feature, forming a source/drain feature on the dielectric feature to fill the source/drain opening;
selectively removing the dummy gate structure;
selectively removing the plurality of sacrificial layers; and
forming a metal gate stack to wrap around each channel layer of the plurality of channel layers.

2. The method of claim 1, wherein the forming of the dielectric feature in the V-shape groove comprises:
conformally depositing a dielectric layer over the workpiece, the dielectric layer comprising a first portion extending along sidewalls of the source/drain opening and a second portion in the V-shape groove;
performing a plasma treatment to the second portion of the dielectric layer; and
performing a third etching process to selectively remove the first portion of the dielectric layer, leaving the treated second portion of the dielectric layer in the V-shape groove.

3. The method of claim 2, wherein the dielectric layer comprises silicon nitride, and the third etching process comprises implementing dilute hydrofluoric acid (DHF).

4. The method of claim 1, wherein an angle between a sidewall of the V-shape groove and a bottom surface of the substrate is between about 50° and about 60°.

5. The method of claim 1, wherein the second etching process comprises a wet etching process.

6. The method of claim 1, further comprising:
selectively etching the sacrificial layers to form inner spacer recesses;
conformally depositing a dielectric layer over the workpiece to fill the inner spacer recesses;
etching back the dielectric layer to form inner spacer features in the inner spacer recesses and a protection layer extending along sidewall surfaces of the channel layers.

7. The method of claim 6, wherein the performing of the second etching process further removes the protection layer.

8. The method of claim 1, further comprising:
after the forming of the dielectric feature, forming a low-k dielectric layer on the dielectric feature,
wherein the source/drain feature is spaced apart from the low-k dielectric layer by the dielectric feature.

9. A method, comprising:
forming a dummy gate structure engaging a semiconductor fin, the semiconductor fin comprising a top portion of a substrate and a vertical stack of alternating channel layers and sacrificial layers thereon;
recessing a portion of the semiconductor fin not covered by the dummy gate structure to form a source/drain opening;
selectively recessing the sacrificial layers to form inner spacer recesses;
forming inner spacer features in the inner spacer recesses;
performing a wet etching process to selectively etch the top portion of the substrate exposed by the source/drain opening, thereby forming an extended source/drain opening;
forming an isolation structure in the extended source/drain opening;
forming a source/drain feature on the isolation structure and in the extended source/drain opening; and
replacing the sacrificial layers and the dummy gate structure with a metal gate stack.

10. The method of claim 9, wherein, the performing of the wet etching process comprises implementing ammonia.

11. The method of claim 9, wherein, in a cross-sectional view, the extended source/drain opening comprises a V-shape lower portion.

12. The method of claim 9, wherein the forming of the source/drain feature comprising forming a doped epitaxial layer in the extended source/drain opening, wherein the doped epitaxial layer is spaced apart form the substrate by the isolation structure.

13. The method of claim 9, wherein the isolation structure comprises a dielectric layer on the substrate and an air gap between the dielectric layer and the source/drain feature.

14. The method of claim 9, wherein the forming of the isolation structure comprises:
conformally depositing a dielectric layer in the extended source/drain opening;
performing a treatment to a portion of the dielectric layer in direct contact with the substrate without treating a remaining portion of the dielectric layer;
selectively removing the remaining portion of the dielectric layer without removing the treated portion of the dielectric layer, thereby forming the isolation structure.

15. The method of claim 9, wherein the substrate comprises (100) silicon, and the extended source/drain opening exposes (111) crystallographic planes of the substrate.

16. A semiconductor structure, comprising:
a vertical stack of channel members disposed over a substrate;
a gate structure wrapping around each channel member of the vertical stack of channel members;
a source/drain feature coupled to the vertical stack of channel members and adjacent the gate structure; and
a dielectric feature disposed between the source/drain feature and the substrate,
wherein, in a cross-sectional view, the dielectric feature comprises a V-shape sidewall surface.

17. The semiconductor structure of claim 16, wherein an entirety of a bottom surface of the source/drain feature is in direct contact with the dielectric feature.

18. The semiconductor structure of claim 16, further comprising:
an air gap disposed between the source/drain feature and the dielectric feature.

19. The semiconductor structure of claim 16, wherein the dielectric feature comprises silicon nitride.

20. The semiconductor structure of claim 16, the V-shape sidewall surface comprises a first sidewall intersecting a second sidewall at a vertex, and the first sidewall comprises a (111) crystallographic plane.
